(19) United States
(12) Patent Application Publication
(10) Pub. No.: US 2007/0108599 A1
(43) Pub. Date: May 17, 2007

(54) Semiconductor chip package with a metal substrate and semiconductor module having the same

(75) Inventors: Yun-Hyeok Im, Yongin-si (KR); Jae-Wook Yoo, Suwon-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 11/477,547

(22) Filed: Jun. 30, 2006

(30) Foreign Application Priority Data
Nov. 15, 2005 (KR) 2005-109178

(51) Int. Cl. H01L 23/34

(52) U.S. Cl. 257/712

(57) ABSTRACT

A semiconductor chip package includes: a metal substrate having a core; a semiconductor chip mounted on the metal substrate; and a heat sink extending from the core.

### PRIORITY STATEMENT

This U.S. non-provisional application claims benefit of priority under 35 U.S.C. §119 of Korean Patent Application No. 2005-109178, filed on Nov. 15, 2005, the disclosure of which is incorporated herein in its entirety by reference.

### BACKGROUND

1. Field of the Present Invention

The present invention relates to a semiconductor device, and more particularly, to a semiconductor chip package exhibiting improved heat dissipation.

2. Description of the Related Art

The temperature of a semiconductor chip may correlate with its electrical characteristic and/or life.

FIG. 1 is a graph of a temperature-life correlation of a conventional semiconductor chip. Referring to FIG. 1, as the operating temperature of a semiconductor chip increases, the operation characteristic of the semiconductor chip may deteriorate, thereby reducing the life of the semiconductor chip. To improve the heat radiating characteristic of a semiconductor chip, the operating temperature of the semiconductor chip should be reduced. For semiconductor devices, e.g., microprocessors, memory devices or other power devices, whose operation is generally negatively impacted by heat generation, a typical design goal is improved heat radiation.

Various solutions have been studied to reduce the temperature of a semiconductor chip at package level, substrate or module level, or system level. For some instances, semiconductor chips, the devices in which they are incorporated impose constraints on the heat radiation techniques that can be used. As an example, a semiconductor chip package or a semiconductor module used in small-sized and/or portable electronic apparatus, such as mobile products, may have difficulties in employing a heat sink and/or creating a heat radiating environment at system level.

FIG. 2 is a cross-sectional view of an example of a conventional semiconductor chip package 710. FIG. 3 is a cross-sectional view of another example of a conventional semiconductor chip package 810.

Referring to FIG. 2, a fine pitch BGA (FBGA) package 710, which may be generally used in mobile products, may have high heat resistance. Thereby, the FBGA package 710 may have a difficulty in applying to high power semiconductor products or semiconductor products having a low maximum junction temperature.

Referring to FIG. 3, a FBGA package 810 may have a heat sink 850 formed in an encapsulant 835. Heat generated by a semiconductor chip 811 may be transmitted to the heat sink 850 through the encapsulant 835.

Since a portion of the heat sink 850 is exposed to the external environment, the FBGA package 810 may have better heat radiation than the FBGA package 710 by about 30%. Although the FBGA package 810 is generally acceptable, it is not without shortcoming. For example, the FBGA package 810 may have a difficulty in transmitting heat to a substrate or a heat sink and may have a disadvantage of increased costs.

### SUMMARY OF THE PRESENT INVENTION

One or more embodiments of the present invention provide a semiconductor chip package with an improved heat radiation using a metal substrate and/or a semiconductor module having the semiconductor chip package.

An embodiment of the invention provides a semiconductor chip package including: a metal substrate having a core; a semiconductor chip mounted on the metal substrate; and a heat sink extending from the core.

Additional features and advantages of the present invention will be more fully apparent from the following detailed description of example embodiments, the accompanying drawings and the associated claims.

### BRIEF DESCRIPTION OF THE DRAWINGS

The patent or application file contains at least one drawing executed in color. Copies of this patent or patent application publication with color drawing(s) will be provided by the U.S. Patent and Trademark Office upon request and payment of the necessary fee.

Example embodiments of the present invention will be readily understood with reference to the following detailed description thereof provided in conjunction with the accompanying drawings, wherein like reference numerals designate like structural elements.

FIG. 1 is a graph of a temperature-life correlation of a conventional semiconductor chip.

FIG. 2 is a cross-sectional view of an example of a conventional semiconductor chip package.

FIG. 3 is a cross-sectional view of another example of a conventional semiconductor chip package.

FIG. 4 is a cross-sectional view of a semiconductor chip package in accordance with an example embodiment of the present invention.

FIG. 5 is a more detailed rendering of a portion of a sample implementation of a metal substrate in the package of FIG. 4.

FIG. 6 is a cross-sectional view of a semiconductor module having a semiconductor chip package in accordance with another example embodiment of the present invention.

FIG. 7 is a cross-sectional view of a plurality of semiconductor modules having semiconductor chip packages of FIG. 6, in accordance with another example embodiment of the present invention.

FIGS. 8 through 10 are plan views of other semiconductor modules having the semiconductor chip package of FIG. 6, according to example embodiments of the present invention, respectively.

FIG. 11 is a cross-sectional view of a semiconductor module having a semiconductor chip package in accordance with another example embodiment of the present invention.

FIG. 12 is a three-quarter perspective view of a simulation model 1200 of a plurality of the semiconductor modules 260 of FIG. 7.

FIG. 15 is a simulated thermal image of the model 1200. For comparison, FIG. 14 is a simulated image of a model (not shown) of a plurality of the chip packages 10 of FIG. 4 (and assuming an FBGA package). For contrast, FIG. 13 is a simulated thermal image of a plurality of conventional FBGAs.

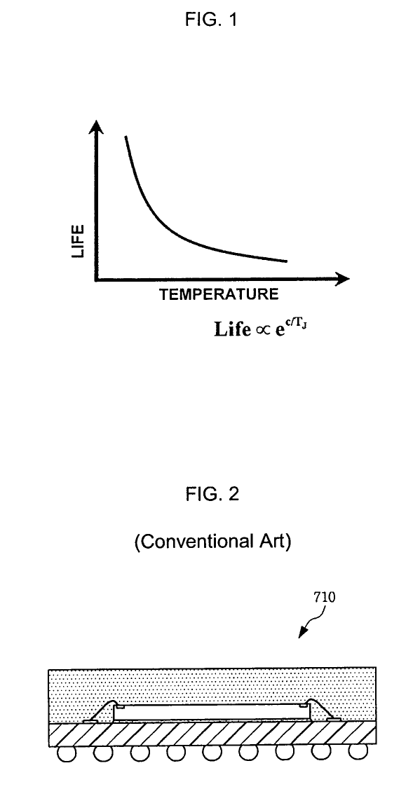

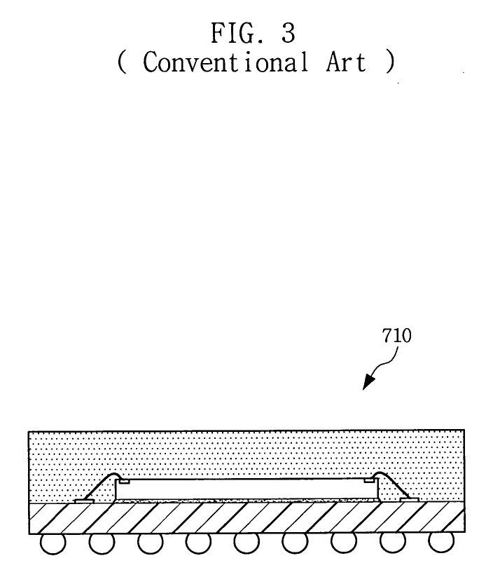

These drawings are provided for illustrative purposes only and are not drawn to scale. The spatial relationships and relative sizing of the elements illustrated in the various embodiments may have been reduced, expanded or rearranged to improve the clarity of the figure with respect to the corresponding description. The figures, therefore, should not be interpreted as accurately reflecting the relative sizing or positioning of the corresponding structural elements that could be encompassed by an actual device manufactured according to the example embodiments of the present invention.

### DETAILED DESCRIPTION OF THE EXAMPLE EMBODIMENTS

It will be understood that if an element or layer is referred to as being “on,” “against,” “connected to” or “coupled to” another element or layer, then it can be directly on, against connected or coupled to the other element or layer, or intervening elements or layers may be present. In contrast, if an element is referred to as being “directly on”, “directly connected to” or “directly coupled to” another element or layer, then there are no intervening elements or layers present. Like numbers refer to like elements throughout. As used herein, the term “and/or” includes any and all combinations of one or more of the associated listed items.

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, term such as “below” can encompass both an orientation of above and below. The device may be otherwise oriented (rotated 90 degrees or at other orientations) and the spatially relative descriptors used herein interpreted accordingly.

Although the terms first, second, etc. may be used herein to describe various elements, components, regions, layers and/or sections, it should be understood that these elements, components, regions, layers and/or sections should not be limited by these terms. These terms are used only to distinguish one element, component, region, layer or section from another region, layer or section. Thus, a first element, component, region, layer or section discussed below could be termed a second element, component, region, layer or section without departing from the teachings of the present invention.

The terminology used herein is for the purpose of describing particular embodiments only and is not intended to be limiting of the present invention. As used herein, the singular forms “a”, “an” and “the” are intended to include the plural forms as well, unless the context clearly indicates otherwise. It will be further understood that the terms “includes” and/or “including”, when used in this specification, specify the presence of stated features, integers, steps, operations, elements, and/or components, but do not preclude the presence or addition of one or more other features, integers, steps, operations, elements, components, and/or groups thereof.

Example, non-limiting embodiments of the present invention will now be described more fully hereinafter with reference to the accompanying drawings. This invention may, however, be embodied in many different forms and should not be construed as limited to the example embodiments set forth herein. Rather, the disclosed example embodiments are provided so that this disclosure will be thorough and complete, and will fully convey the scope of the invention to those skilled in the art. The principles and features of the present invention may be employed in varied and numerous embodiments without departing from the scope of the invention.

Further, well-known structures and processes are not described or illustrated in detail. Like reference numerals are used for like and corresponding parts of the various drawings.

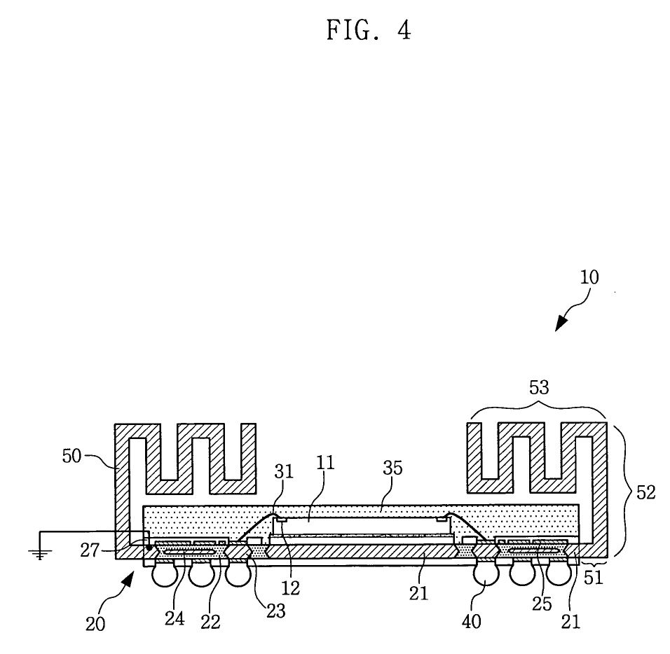

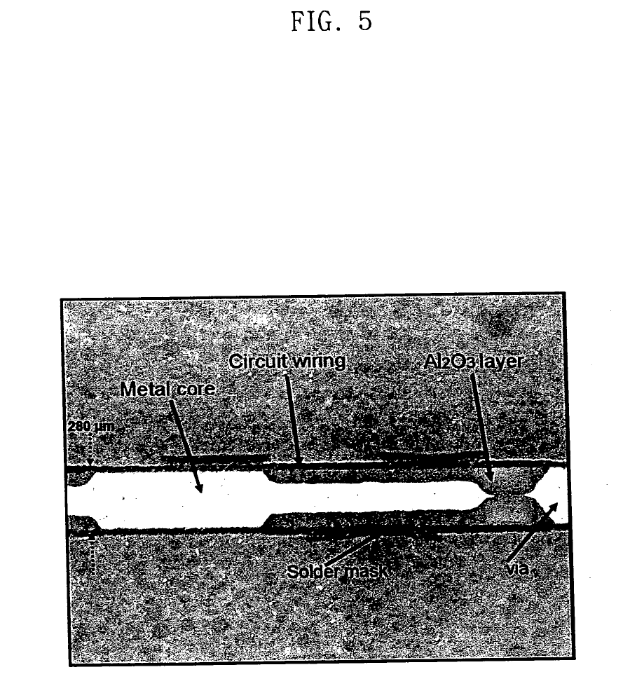

FIG. 4 is a cross-sectional view of a semiconductor chip package 10 in accordance with an example embodiment of the present invention. FIG. 5 is a more detailed rendering of a portion of a sample implementation of a metal substrate 20 in the package 10.

Referring to FIGS. 4 and 5, the semiconductor chip package 10 may use the metal substrate 20 as a chip mounting substrate. The metal substrate 20 may have a metal core 21, e.g., aluminum. A metal core heat sink 50 may extend from the metal core 21 to facilitate to heat radiation. The metal core heat sink 50 may be formed bent or folded repetitively (or pleated), thereby increasing its surface area per given volume, i.e., its convection capability.

The metal substrate 20 may use an Al2O3 layer 22, which may be formed by oxidizing an aluminum plate, as an insulating layer. The metal substrate 20 may use the metal core 21 as a via 23 and an inner metal layer 24. A circuit wiring 25 may be provided on the metal core 21 and the Al2O3 layer 22. A solder mask 27 may be provided on an upper surface and a lower surface of the metal substrate 20 to protect the circuit wiring 25. A circuit wiring forming area and a solder ball attaching area may be exposed from the solder mask 27.

The metal core 21 may occupy the majority of volume in the metal substrate 20. As such, the metal substrate 20, in particular, the method core 21 (again, e.g., aluminum), should have good thermal conductivity and low electrical noise, and in the physical aspect, have a lower coefficient of thermal expansion than an encapsulant 35, e.g., BT resin or FR-4. An instance of a metal core having such characteristics it may eliminate the need for a via formed in the shape of a dog bone, thereby allowing for high routing density. The sample implementation of the metal substrate 20 in FIG. 5 has a thickness of about 280 μm.

A semiconductor chip 11 is, e.g., an edge pad-type, having chip pads 12 arranged along the edges. The semiconductor chip 11 may be mounted on the upper surface of the metal substrate 20 and be electrically connected to the metal substrate 20 using wire bonding.

Specifically, the semiconductor chip 11 may be attached using an adhesive to the metal core 21 of the metal substrate 20. Alternatively, the semiconductor chip 11 may be attached to the Al2O3 layer 22. As between the two, it may be preferable to attach the semiconductor chip 11 to the metal core 21 in the respect of heat transmission. Heat may be transmitted more easily and rapidly from the semiconductor chip 11 to the metal core 21 than to the Al2O3 layer 22. A chip adhesive may include a liquid adhesive such as an epoxy, and a solid adhesive such as an adhesive tape. The chip adhesive should have good thermal conductivity and heat transmission.

Alternatively, the semiconductor chip 11 may be a center pad-type semiconductor chip, of which chip pads may be arranged in the center. However, in consideration of wire bonding, an edge pad-type semiconductor chip may be preferable.

The wire bonding may be made such that one end of a bonding wire 31 may be, e.g., ball-bonded to the chip pad 12 and the other end of the bonding wire 31 may be, e.g., wedge-bonded to the circuit wiring 25. Alternatively, for example, it may be possible to apply to a reverse wire bonding method, in which one end of a bonding wire may be ball-bonded to the circuit wiring 25 and the other end of the bonding wire may be wedge-bonded to the chip pad 12. The bonding wire 31 may be formed from, e.g., gold.

Although the package 10 shows the mechanical mounting using an adhesive and the electrical connection using a wire bonding, the mechanical mounting structure and/or electrical connection structure of the semiconductor chip 11 should be not limited in this regard. For example, a flip chip bonding method may be applied to the mechanical and electrical connection structure of the semiconductor chip 11. Or, the semiconductor chip 11 may be electrically connected to the circuit wiring 25 using a tape wiring substrate or other electrical connection structures, etc.

An encapsulant 35 may be provided on the upper surface of the metal substrate 20 to protect the semiconductor chip 11 and the bonding wire 31. The encapsulant 35 may be formed from an epoxy molding compound. The encapsulant 35 may cover the metal substrate 20 entirely or partially.

The metal core heat sink 50 may include a first portion 51, a second portion 52 and a third portion 53. The first portion 51 may extend horizontally from the metal core 21 of the metal substrate 20. The second portion 52 may be formed perpendicular to the metal substrate 20. The third portion 53, which may be configured for increased surface area per given volume, may be formed parallel to the metal substrate 20.

The third portion 53 may be located above the metal substrate 20 for reduced width of a semiconductor chip package 10. The third portion 53 may be repetitively bent (or folded or pleated) to increase the contact area with air. Although the package 10 shows the third portion 53 of a concavo-convex shape, the third portion 53 may be formed in various shapes, for example a fan shape.

To reduce the entire width of a package, the size of the first portion 51 should be reduced or the first portion 51 may be not created during a manufacturing process. The size of the second portion 52 may be adjusted according to the height and/or shape a bent portion of the third portion 53. The size or the bent portion of the third portion 53 may be adjusted depending on the width or the thickness of a package and/or degree of heat radiation.

The metal core heat sink 50 may extend from the metal core 21 at opposing sides of the metal substrate 20. Alternatively, the metal core heat sink 50 may extend from the metal core 21 at four sides of the metal substrate 20 or one side of the metal substrate 20, etc.

The metal core 21 may be electrically connected to the chip pad 12, serving as a ground terminal of the semiconductor chip 11. Therefore, the metal core heat sink 50 may function as grounding as well as heat radiation.

External connection terminals, e.g., solder balls 40, may be provided on the lower surface of the metal substrate 20 in a matrix arrangement. The solder balls 40 may be arranged on the entire surface or a partial surface of the metal substrate 20. The solder balls 40 may be replaced with other bumps.

The semiconductor chip package 10 may include the metal substrate 20 having the semiconductor chip 11 and the metal core heat sink 50 formed integrally with the metal substrate 20. Heat may be transmitted from the semiconductor chip 11 to the metal core heat sink 50 through the metal substrate 20. For example, heat generated by the semiconductor chip 11 may be transmitted to the metal core 21 having good thermal conductivity and be radiated through the metal core heat sink 50 to the ambient environment. The use of the metal core heat sink 50 may allow for prompt and effective heat radiation, compared to the use of a separate heat sink. Therefore, the operation characteristic of the semiconductor chip 11 at package level or system level may be improved and solder joint reliability may be improved.

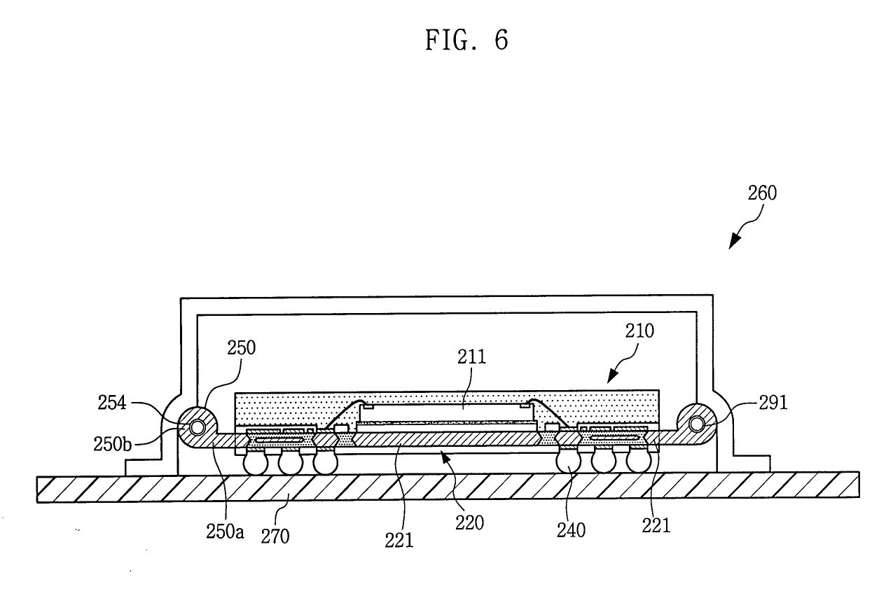

FIG. 6 is a cross-sectional view of a semiconductor module 260 having a semiconductor chip package 210 in accordance with another example embodiment of the present invention.

Referring to FIG. 6, the semiconductor chip package 210 may have a similar structure to the semiconductor chip package 10, in that a metal core heat sink 250 may extend from a metal core 221 of a metal substrate 220. For example, a first portion 250a of the metal core heat sink 250 may extend horizontally from the metal core 221 of the metal substrate 220.

The semiconductor module 260 may comprise the semiconductor chip package 210, a module substrate 270 and an optional module protection housing (not shown). The semiconductor chip package 210 may be mounted on the module substrate 270. The module protection housing may be provided on the module substrate 270 to protect the semiconductor chip package 210 from the external environment. The module protection housing may be formed from metal and may be fixed to the module substrate using, for example, a screw, etc.

The semiconductor module 260 may be characterized by the third portion 253 being attached to the module protection housing. The metal core heat sink 250 may be attached to the module protection housing using an adhesive. The adhesive may include an adhesive tape. The adhesive may be formed from material having good thermal conductivity, so that heat may be transmitted from the metal core heat sink 250 to the module protection housing.

Heat generated by the semiconductor chip package 210 may be transmitted to the module protection housing through the metal core heat sink 250. The module protection housing may have lower temperature and larger volume than the semiconductor chip package 210 so that contact between the metal core heat sink 250 and the module protection housing may allow for reduced temperature of the semiconductor chip package 210. The module protection housing may include other metal structures outside of the module substrate 270. Similar module protection housings can be adapted for optional use with the other presently disclosed example embodiments.

In FIG. 6, the semiconductor chip package 210 may include a metal core heat sink 250 having a first portion 250a and a second portion 250b that has a cylindrical or rolled shape. The first portion 250a may extend horizontally from a metal substrate 220. A hole 254 may be provided in the second portion 250b and be formed parallel to one side of the metal substrate 220.

The metal core heat sink 250 may extend from a metal core 221 towards the opposing sides of the metal substrate 220. A semiconductor chip 211 may be mounted on the metal core 221. Heat may be transmitted from the semiconductor chip 211 to the metal core heat sink 250 through the metal core 221. Alternatively, the metal core heat sink 250 may extend from the metal core 221 at four sides of the metal substrate 220 or at one side of the metal substrate 220. The hole 254 may be a plurality of holes. The second portion 250b may be formed of various shapes, for example a semicircle.

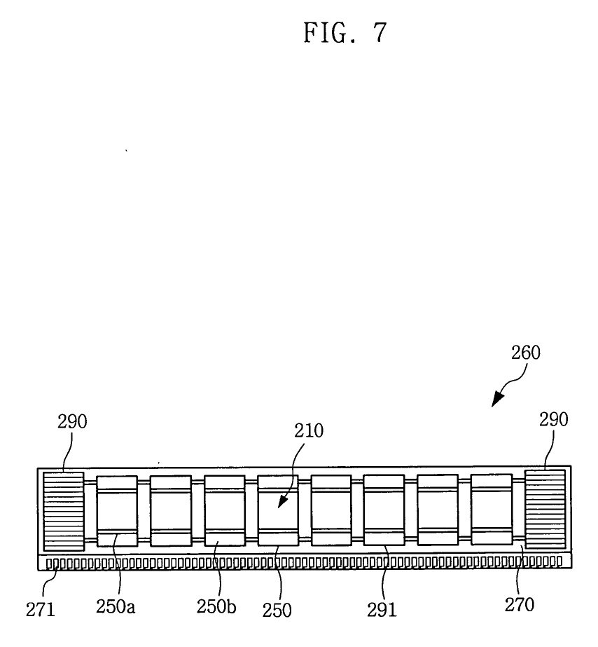

FIG. 7 is a plan view of a plurality of semiconductor modules 260 having semiconductor chip packages 210 in accordance with another example embodiment of the present invention.

The semiconductor module 260 may comprise the semiconductor chip package 210, a module substrate 270, a heat pipe 291 and a heat sink block 290. A plurality of the semiconductor chip packages 210 may be mounted on the module substrate 270. The semiconductor chip packages 210 may be arranged in a first direction of the module substrate 270. The hole 254 of the metal core heat sink 250 may be formed in the first direction of the module substrate 270. The semiconductor chip package 210 may be provided on at least one surface of the module substrate 270.

The heat pipe 291 may run in a first direction of the module substrate 270, passing through the metal core heat sink 250 of the semiconductor chip package 210. This can be described as the heat pipe 291 series-connecting the chip packages 210. The heat pipe 291 may be fixed into the hole 254 of the metal core heat sink 250. A working fluid may undergo a gas-to-liquid phase change in an airtight internal space of the heat pipe 291, so that the heat pipe 291 may transmit heat to the heat sink block 290. The heat pipe 291 may be fixed to the metal core heat sink 250 using an adhesive or soldering. The heat pipe 291 may be replaced with a heat bar.

Ends of the heat pipe 291 may be connected to the heat sink block 290. The heat sink block 290 may be arranged at the opposing ends of the module substrate 270. Alternatively, the heat sink block 290 may be arranged at four edges or one edge of the module substrate 270, etc. The heat sink block 290 may be formed from metal and may have a top portion with protrusions (fins) to increase the contact area with air. However, the shape of the heat sink block 290 should not be limited in this regard.

Heat generated by the semiconductor chip package 210 may be transmitted to the metal core heat sink 250 through the metal core 221, and then may be radiated to the heat pipe 291, which may be referred to as a first heat radiation. The heat may be radiated from the heat pipe 291 to the heat sink block 290, which may be referred to as a second heat radiation.

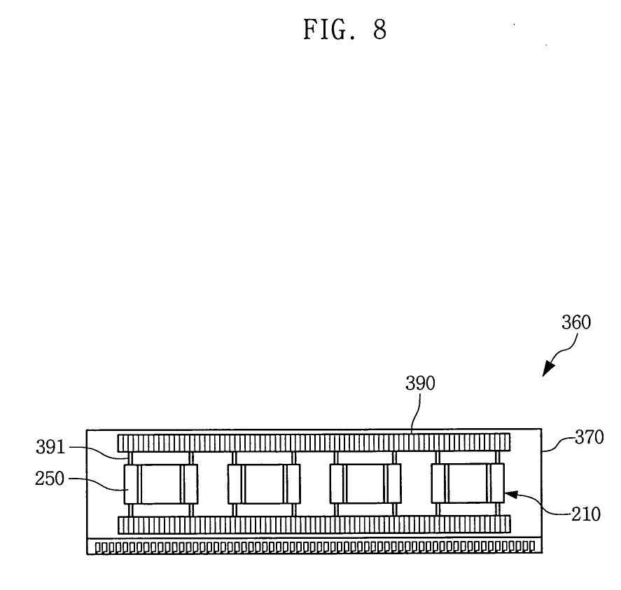

FIGS. 8 through 10 are plan views of example embodiments of the semiconductor modules 360, 460 and 560, respectively, having a semiconductor chip package 210.

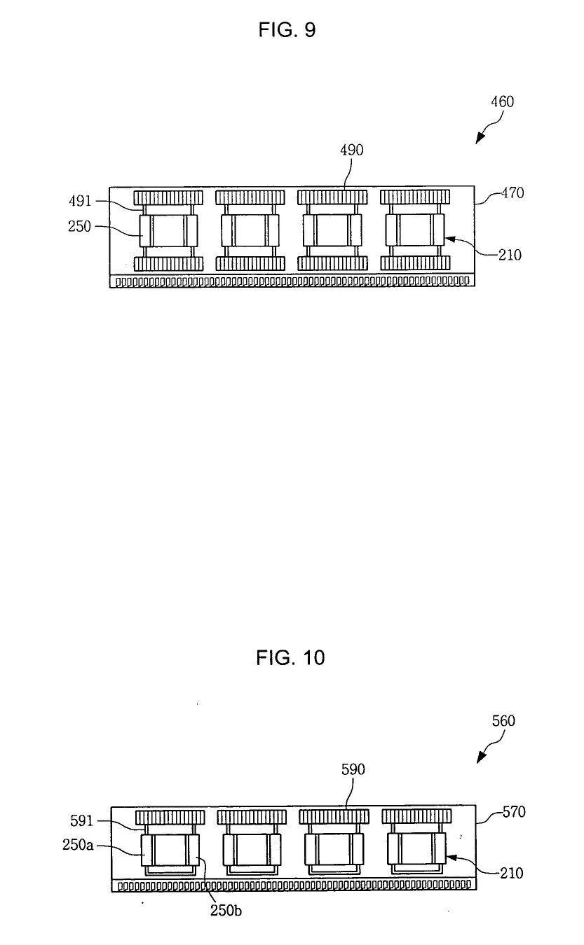

Referring to FIG. 9, the semiconductor module 360 may comprise heat sink blocks 390 arranged at opposing sides in a second direction of a module substrate 370. A heat pipe 391 may run in a first direction of the module substrate 370. A plurality of semiconductor chip packages 210 may be provided such that a metal core heat sink 250 may be arranged in the first direction of the module substrate 370. The heat pipe 250 may be connected to the heat sink block 390, passing through the metal core heat sink 391. In the module 460, multiple heat pipes 391 can be described as parallel-connecting multiple chip packages 210 to the heat sink block 390, respectively.

Further as to FIG. 9, the semiconductor module 460 may comprise individual heat sink blocks 490 for each semiconductor chip package 210. The heat sink blocks 490 may be arranged at opposing sides thereof in a second direction of the module substrate 470. A heat pipe 491 may be connected to the corresponding heat sink block 490, passing through a metal core heat sink 250 for each semiconductor chip package 210. In the module 460, the semiconductor module 460 may have a plurality of the heat sink blocks 490.

Referring to FIG. 10, a semiconductor module 560 may comprise a heat sink block 590 arranged along one side of a module substrate 570. A heat pipe 591 may pass through one metal core heat sink 250a and the other core heat sink 250b and return the heat sink block 590. In the module 560, the heat sink block 590 may be arranged at one side of the module substrate 570 and a single heat pipe 591 may be provided for each semiconductor chip package 21.

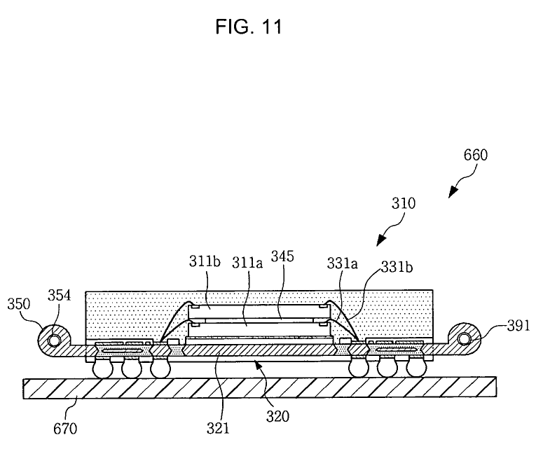

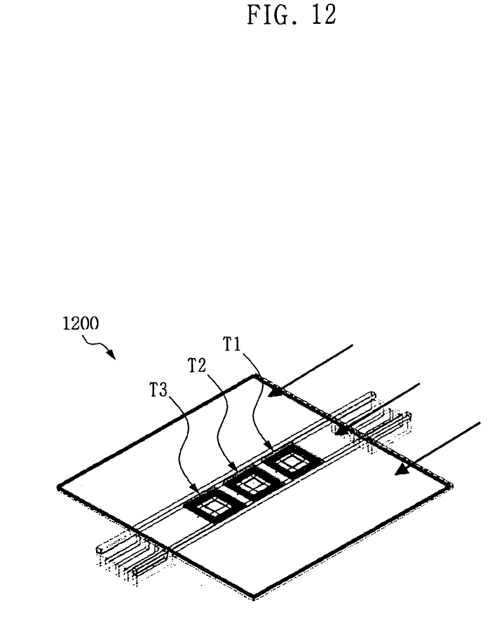

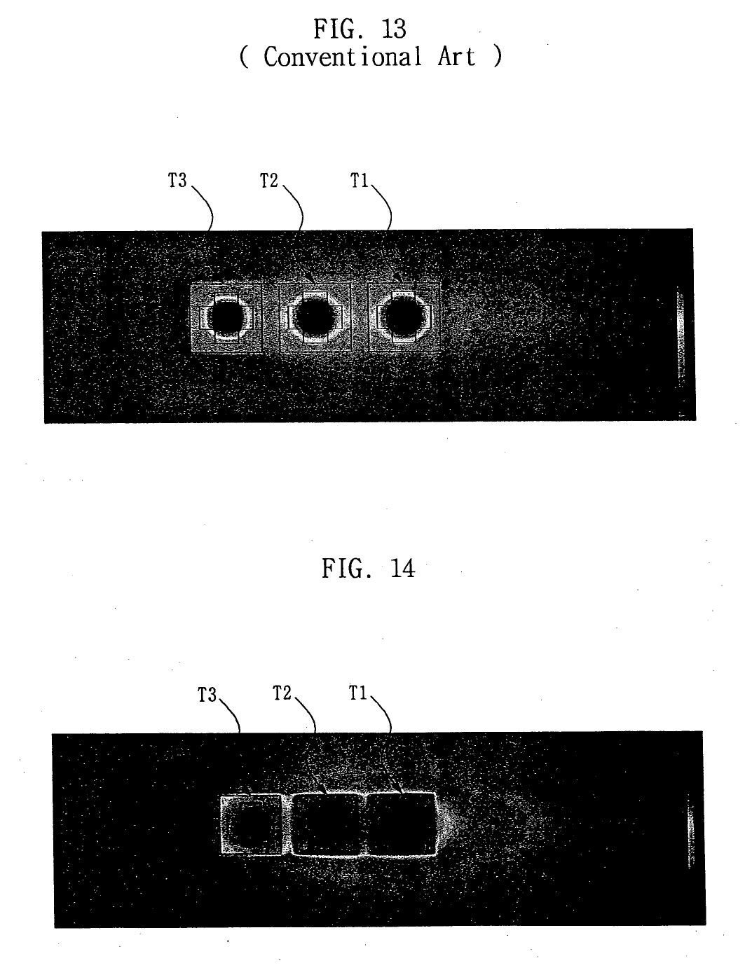

FIG. 11 is a cross-sectional view of a semiconductor module 660 having a semiconductor chip package 310 in accordance with another example embodiment of the present invention.

Referring to FIG. 11, the semiconductor chip package 310 (as a chip stack type of package having a plurality of semiconductor chips) may include a lower semiconductor chip 311a and an upper semiconductor chip 311b. An interposer 345 may be provided between the lower semiconductor chip 311a and the upper semiconductor chips 311b . A purpose of the interposer 345 can be to create a gap between the lower and upper chips 311a and 311b sufficient to accommodate the height of a wire loop of a bonding wire 331a connected to the lower semiconductor chip 311a.

Heat generated by the semiconductor chips 311a and 311b may be transmitted to a metal core 321 through a metal substrate 320. The heat may also be transmitted to the metal core 321 through bonding wires 311a and 311b . The heat may be radiated via a metal core heat sink 350 to the ambient external environment.

The semiconductor module 660 may comprise the semiconductor chip package 310, a module substrate 670, a metal core heat sink 350 and a heat pipe 391. The heat pipe 391 may be fixed to a metal core 354 of the metal core heat sink 350. In the module 660, the metal core heat sink 350 may radiate heat generated by a plurality of the semiconductor chips 311a and 311b.

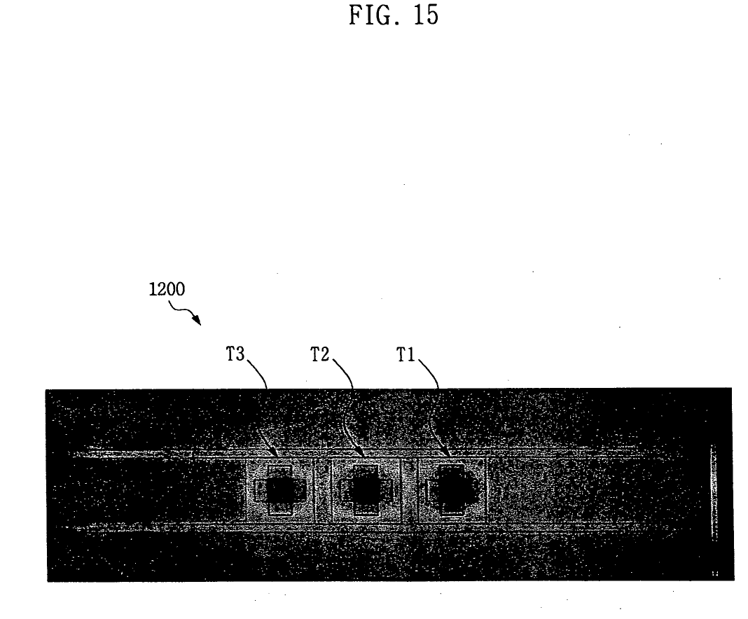

FIG. 12 is a three-quarter perspective view of a simulation model 1200 of a plurality of the semiconductor modules 260 of FIG. 7.

FIG. 15 is a simulated thermal image of the model 1200. For comparison, FIG. 14 is a simulated image of a model (not shown) of a plurality of the chip packages 10 of FIG. 4 (and assuming an FBGA package). For contrast, FIG. 13 is a simulated thermal image of a plurality of conventional FBGAs.

Referring to FIG. 12, the simulation may be applied to different semiconductor module structures, for example a semiconductor module having a typical FBGA package, a semiconductor module having a FBGA package with a metal core heat sink, and a semiconductor module having a FBGA package with a metal core heat sink having a heat pipe.

The simulation model of FIG. 12 is assumed to have the following conditions: a 304FBGA—16×16 is mounted on a stack of four boards of 101.6 mm×114.5 mm at 20 mm pitches and air at 1 m/sec blows in the direction of an arrow. Here, the speed of 1 m/sec may be set, taking the internal speed of a typical desktop computer being 1 m/sec into consideration. The neighborhood temperature (Ta) may be 20° C. and power may be 1 W/chip. For example, the semiconductor chip located nearest an inflow of air may be referred to as T1. The semiconductor chip located farthest an inflow of air may be referred to as T3.

Table 1 (below) shows data corresponding to the simulated thermal images of FIGS. 13-15, specifically the temperatures of the semiconductor chips T1-T3, respectively. In Table 1, the data is to be understood as approximate, e.g., the temperature of chip T1 in FIG. 13 is about 67.5° C., etc.

TABLE 1

| | Semiconductor module | | | |
|---|---|---|---|---|
| FIG. | structure | T1 | T2 | T3 |
| 13 | A conventional FBGA | 67.5° C. | 71.0° C. | 71.7° C. |
| 14 | A metal substrate FBGA | 49.3° C. | 52.8° C. | 52.6° C. |
| 15 | A metal substrate FBGA | 45.0° C. | 46.0° C. | 46.0° C. |
| | with a heat pipe | | | |

As shown in Table 1 and FIG. 14, a semiconductor module having a metal substrate may have lower temperature of a semiconductor chip than a conventional semiconductor module having a typical FBGA package (as in FIG. 13) by about 18° C. or more. A semiconductor module having a metal substrate FBGA package with a heat pipe (as in FIG. 15) may generate at a lower temperature of a semiconductor chip than the semiconductor module having a metal substrate FBGA by about 6° C.

A semiconductor module having a typical FBGA package may have the differences of temperature among T1, T2 and T3 by about 4° C. A semiconductor module having a metal substrate FBGA package may have the differences of temperature among T1, T2 and T3 by about 3° C. A semiconductor module having a metal substrate FBGA package with a heat pipe may have the differences of temperature among T1, T2 and T3 by about 1° C.

Therefore, FIG. 15 shows that a semiconductor module having a metal substrate FBGA package with a heat pipe may reduce the likelihood that heat may concentrate on a specific semiconductor chip.

The simulation assumes that air is blown directly onto a semiconductor chip package. If such air is not being blown, then the heat pipe may increase the temperature reduction. Although the simulations show the use of a single semiconductor module, a plurality of semiconductor modules may be arranged parallel to each other. In this case, there may be greater differences of temperature between semiconductor chips, thereby improving the temperature reduction effect by a heat pipe.

According to one or more embodiments of the present invention, a semiconductor chip package may include a metal core heat sink extending from a metal core of a metal substrate. Heat generated by a semiconductor chip may be radiated through the metal substrate and the metal core heat sink. The metal core heat sink may be attached to an external metal structure or may be connected to a heat pipe and a heat sink block, thereby improving the heat radiation and reducing the hot spot phenomenon. Such cooling facilitates a semiconductor chip operating stably, with faults caused by thermal stresses (for example, a solder joint crack) possibly being reduced. A reduced (if not minimized) heat radiating environment for a semiconductor chip may be easily created, and operation reliability of a semiconductor chip under a thermal environment at package level, module level or system level may be improved. For example, the metal core heat sink may be located at the sides of the semiconductor chip package and fixed by a heat pipe, thereby reducing (if not eliminating) the need of increased thickness of a semiconductor chip package.

Further, according to one or more embodiments of the present invention, a metal substrate, a metal core heat sink, an external metal structure, a heat pipe and/or a heat sink block may be incorporated at relatively low costs.

Although example, non-limiting embodiments of the present invention have been described in detail hereinabove, it should be understood that many variations and/or modifications of the basic inventive concepts herein taught, which may appear to those skilled in the art, will still fall within the spirit and scope of the example embodiments of the present invention as defined by the associated claims.

What is claimed is:

1. A semiconductor chip package including:
a metal substrate having a core;
a semiconductor chip mounted on the metal substrate; and
a heat sink extending from the core.

2. The package of claim 1, wherein the heat sink has a bent portion.

3. The package of claim 2, wherein the bent portion is located above the metal substrate.

4. The package of claim 1, wherein the bent portion has a concavo-convex structure.

5. The package of claim 1, wherein the heat sink includes a first portion extending horizontally from the metal substrate, a second portion extending perpendicularly to the metal substrate, and a third portion extending above the metal substrate.

6. The package of claim 1, wherein the heat sink has a portion formed parallel to a chip mounting area of the sink metal substrate.

7. The package of claim 6, wherein the parallel portion extends toward an interior of the metal substrate.

8. The package of claim 6, wherein the parallel portion extends away from the metal substrate.

9. The package of claim 1, wherein the heat sink has a hole formed parallel to the metal substrate.

10. The package of claim 9, wherein a portion of the heat sink has a rolled shape.

11. The package of claim 1, wherein the heat sink extends from the core to at least one side of the metal substrate.

12. The package of claim 1, wherein the heat sink is electrically connected to a ground terminal of the semiconductor chip.

13. The package of claim 1, wherein the semiconductor chip is attached to the core.

14. The package of claim 1, wherein the package includes plural instances of the semiconductor chip stacked vertically.

15. A semiconductor module including:
a module substrate;
a package mounted on the module substrate, the package including a semiconductor chip, a metal substrate having a core, and a heat sink extending from the core; and
an external metal structure provided on the module substrate.

16. The module of claim 15, wherein the external metal structure is a housing that covers the package and is attached to the module substrate.

17. The module of claim 15, wherein the heat sink is attached to the external metal structure using a heat conductive adhesive.

18. The module of claim 15, wherein heat sink has a portion formed parallel to a chip mounting area of the metal substrate and the parallel portion is attached to the external metal structure.

19. The module of claim 15, wherein the heat sink extends from the core to at least one side of the metal substrate.

20. The module of claim 15, wherein the heat sink is electrically connected to a ground terminal of the semiconductor chip.

21. The module of claim 15, wherein the semiconductor chip is attached to the core.

22. The module of claim 15, wherein the package includes plural instances of the semiconductor chip stacked vertically.

23. A semiconductor module comprising:
a module substrate;
a package mounted on the module substrate, the package including a semiconductor chip, a metal substrate having a core, and a heat sink extending from the core; and
a heat pipe coupled with the heat sink of the semiconductor chip package.

24. The module of claim 23, further comprising a heat sink block connected to the heat pipe.

25. The module of claim 24, wherein the heat sink block is disposed to at least one side of the module substrate.

26. The module of claim 23, further comprising plural instances of the semiconductor chip package arranged in a first direction of the module substrate.

27. The module of claim 26, wherein the heat pipe is arranged parallel to a row into which the semiconductor chip packages arranged.

28. The module of claim 26, further comprising plural instances of the heat pipe arranged in a plurality of rows.

29. The module of claim 26, wherein the heat pipe is arranged in a second direction of the module substrate.

30. The module of claim 23, wherein the heat sink has a hole, through which the heat pipe passes.

31. The module of claim 23, wherein a portion of the heat sink has a rolled shape.

32. The module of claim 23, wherein the heat sink extends from the core to at least one side of the metal substrate.

33. The module of claim 23, wherein the heat sink is electrically connected to a ground terminal of the semiconductor chip.

34. The module of claim 23, wherein the semiconductor chip is attached to the core.

35. The module of claim 23, wherein the package includes plural instances of the semiconductor chip stacked vertically.
